(19) United States
(12) Patent Application Publication
(10) Pub. No.: US 2026/0245605 A1
(43) Pub. Date: Aug. 20, 2026

(54) VOLTAGE SENSE AMPLIFIER FOR 2T2MTJ MAGNETORESISTIVE RANDOM ACCESS MEMORY

(71) Applicant: UIF (University Industry Foundation), Yonsei University, Seoul (KR)

(72) Inventors: Seong-OoK Jung, Seoul (KR); Se Keon Kim, Seoul (KR)

(21) Appl. No.: 19/434,881

(22) Filed: Dec. 29, 2025

(30) Foreign Application Priority Data
Feb. 17, 2025 (KR) 10-2025-0020146

(51) Int. Cl. G11C 11/16; G11C 5/06; G11C 5/10; H10B 61/00; H10N 50/10

(52) U.S. Cl. CPC G11C 11/1673; G11C 5/063; G11C 5/10; G11C 11/1697; H10B 61/22; H10N 50/10

(57) ABSTRACT

The voltage sense amplifier includes a first inverter; a second inverter; a first transistor configured to connect a ground voltage VSS and a node X1, which is one end of the first inverter, in response to a sense-amplifier enable signal SAE; a second transistor configured to connect the ground voltage VSS and a node X2, which is one end of the second inverter, in response to the sense-amplifier enable signal; a third transistor configured to connect a supply voltage VDD and a node Y1, which is the other end of the first inverter, in response to a complementary sense-amplifier enable signal SAEB; and a fourth transistor configured to connect the supply voltage VDD and a node Y2, which is the other end of the second inverter, in response to the complementary sense-amplifier enable signal.

### CROSS-REFERENCE TO RELATED APPLICATION

The present application claims priority under 35 U.S.C. § 119(a) to Korean patent application number 10-2025-0020146 filed on Feb. 17, 2025 in the Korean Intellectual Property Office, the entire disclosure of which is incorporated by reference herein.

### BACKGROUND

### 1. Technical Field

The present disclosure relates to magnetic memory control technology, and more particularly, to a voltage sense amplifier for read and write operations of a magnetic memory.

### 2. Related Art

A magnetic memory or magnetoresistive random access memory (MRAM) is a type of a memory using a magnetic tunnel junction (MTJ), which utilizes the fact that the resistance of the device varies depending on the relative magnetization directions of the two ferromagnetic layers forming the MTJ.

Among such memories, spin-transfer torque MRAM (STT-MRAM) is a type of MRAM in which the magnetization direction of an MTJ is switched by directly supplying a current to the MTJ, rather than by supplying a current to a digit line connected to the MTJ to switch the magnetization direction.

STT-MTJs used in STT-MRAM are regarded as promising next-generation memory devices because they are compatible with CMOS technology, have high endurance, and are capable of fast read/write operation and high density.

STT-MRAM is generally classified into a 1T1MTJ structure having one transistor and one MTJ for each memory cell, and a 2T2MTJ structure having two transistors and two MTJs for each memory cell.

The 1T1MTJ structure provides high bit density because it includes fewer devices but suffers from a small sensing margin and requires a reference cell, whereas the 2T2MTJ structure provides lower bit density but offers a wide sensing margin and does not require a reference cell.

In such a memory device, in order to read a stored value, a change in a voltage value of a bit line is sensed, and since this change is very small, a voltage sense amplifier (VSA) is used to amplify the voltage change.

FIG. 9 illustrates an example of a voltage sense amplifier according to the related art.

First, outputs Q and QB of the voltage sense amplifier are precharged to a voltage VDD, and the source line SL and the complementary source line SLB of the memory cell are driven to a ground voltage VSS during a read operation.

Next, when a word-line voltage WL is turned on from VSS to VDD, a difference Δ_{BL} between a bit-line voltage V_{BL} and a complementary bit-line voltage V_{BLB} occurs due to a resistance difference of an MTJ device.

When a sense-amplifier enable signal SAE is turned on to the supply voltage VDD at this time, the voltage difference Δ_{BL} is amplified and appears as a difference between the outputs Q and QB.

However, in such a voltage sense amplifier of the related art, SAE must be turned on at a point where ΔBL reaches its maximum in order to sense the voltage, and it is difficult to secure a sufficient sensing margin because variations exist between memory cells. In addition, sensing sensitivity may be reduced due to a mismatch between transistors N1 and N2, which receive the bit-line BL and complementary bit-line BLB voltages as gate inputs.

In addition, a large amount of energy is consumed to precharge the bit line BL and the complementary bit line BLB, and in a low-voltage region, that is, when the BL and BLB are close to the threshold voltage, the transistors do not operate properly, resulting in a region in which sensing is not possible.

The disclosure of this section is to provide background information. Applicant does not admit that any information contained in this section constitutes prior art.

### SUMMARY

The inventors of the present disclosure have conducted research to on voltage sense amplifiers. As a result of extensive efforts to provide a charge-sharing type voltage sense amplifier and a control method thereof, which can improve the technologies such as sensing margin, sensing sensitivity, and power consumption, the present disclosure has been completed.

An aspect of the present disclosure provides a voltage sense amplifier capable of improving sensing performance by sensing voltage variations of both a bit line and a source line of a memory cell.

Another aspect of the present disclosure is to reduce precharge energy by employing charge sharing in which both the bit line and the source line are precharged.

Meanwhile, other objects not explicitly stated in this disclosure will be further considered within the scope readily inferred from the following detailed description and its effects.

The voltage sense amplifier according to the present disclosure may include a first inverter having an input terminal coupled to a complementary output QB of the voltage sense amplifier and an output terminal coupled to an output Q of the voltage sense amplifier; a second inverter having an input terminal coupled to an output Q of the voltage sense amplifier and an output terminal coupled to a complementary output QB of the voltage sense amplifier; a first transistor configured to connect a ground voltage VSS and a node X1, which is one end of the first inverter, in response to a sense-amplifier enable signal SAE; a second transistor configured to connect the ground voltage VSS and a node X2, which is one end of the second inverter, in response to the sense-amplifier enable signal; a third transistor configured to connect a supply voltage VDD and a node Y1, which is the other end of the first inverter, in response to a complementary sense-amplifier enable signal SAEB; and a fourth transistor configured to connect the supply voltage VDD and a node Y2, which is the other end of the second inverter, in response to the complementary sense-amplifier enable signal, wherein a bit line and a complementary bit line are precharged to the supply voltage VDD prior to a read operation of the memory cell, and a source line and a complementary source line are precharged to the ground voltage VSS prior to the read operation of the memory cell.

The voltage sense amplifier further may include a first capacitor connected between the node X1 and the bit line of the memory cell; a third capacitor connected between the node Y1 and the complementary source line of the memory cell; a second capacitor connected between the node X2 and the complementary bit line of the memory cell; and a fourth capacitor connected between the node Y2 and the source line of the memory cell.

The memory cell may be a 2T2MTJ-structured memory cell including two transistors and two magnetic tunnel junctions (MTJs).

The first and second transistors may be n-type metal-oxide semiconductor field effect transistors (nMOSFETs), and the third and fourth transistors are p-type metal-oxide semiconductor field effect transistors (pMOSFETs).

The voltage sense amplifier may include a switch connected between an input of the first inverter and an input of the second inverter and configured to equalize voltages between the inputs.

After the precharge, a sense-amplifier enable signal may be switched to the ground voltage and a complementary sense-amplifier enable signal may be switched to the supply voltage, such that the first to fourth transistors are turned off, the nodes X1 and X2 become floating at the ground voltage, the nodes Y1 and Y2 become floating at the supply voltage, and the switch is turned on and connects the input of the first inverter and the input of the second inverter, whereby offset sampling is performed in which both the output and the complementary output of the voltage sense amplifier are equalized to one half of the supply voltage.

After the offset sampling, a word line of the memory cell may be turned on such that the bit line and the complementary bit line may be discharged and the source line and the complementary source line are charged, and a voltage difference between the output and the complementary output of the voltage sense amplifier may be amplified due to a difference in discharge and charging speeds caused by a resistance difference of the memory cell.

After the amplification of the voltage difference, the sense-amplifier enable signal may be switched to the supply voltage and the complementary sense-amplifier enable signal may be switched to the ground voltage such that the first to fourth transistors are turned on, the nodes X1 and X2 are driven to the ground voltage, and the nodes Y1 and Y2 are driven to the supply voltage, whereby the output and the complementary output of the voltage sense amplifier are latched to the supply voltage or the ground voltage.

According to the present disclosure, sensing margin can be increased by sensing and amplifying voltage variations of both the bit line and the source line of a 2T2MTJ-structured memory cell.

In addition, by precharging both the bit line and the source line, power consumed for precharging can be reduced.

On the other hand, even effects not explicitly mentioned herein, the effects and potential effects described in the following specification, which are expected from the technical features of this disclosure, are to be treated as described in the specification of this disclosure.

### BRIEF DESCRIPTION OF THE DRAWINGS

FIG. 1 is a schematic diagram illustrating a voltage sense amplifier according to an embodiment of this disclosure.

FIG. 2 illustrates an example of a memory cell to which a voltage sense amplifier according to an embodiment of this disclosure is connected.

FIGS. 3A and 3B to FIGS. 6A and 6B illustrate schematic operations of respective stages of the voltage sense amplifier according to an embodiment of the present disclosure.

FIGS. 7A, 7B and 8 illustrate performance simulation results of the voltage sense amplifier according to an embodiment of the present disclosure.

FIG. 9 illustrates an example of a voltage sense amplifier according to the related art.

The accompanying drawings are provided by way of reference to aid in understanding the technical concept of this disclosure, and the scope of this disclosure is not limited thereby.

### DETAILED DESCRIPTION

This invention was made with support from a National Research and Development Program of the Republic of Korea. Details of the supporting program are as follows:
[Project Identification Number] 2710008026
[Project Number] 00222085
[Ministry] Ministry of Science and ICT (MSIT)
[Managing Agency] Institute of Information & Communications Technology Planning & Evaluation (IITP)
[Program Title] Core Technology Development for PIM Artificial Intelligence Semiconductors (Design)
[Project Title] Development of a Non-Volatile PIM Memory Module and Memory Compiler Optimized for Data Characteristics and Data Access Patterns of an AI Processor
[Performing Organization] Yonsei University
[Research Period] Jan. 1, 2024-Dec. 31, 2024

Hereinafter, specific embodiments of the present disclosure will be described with reference to the accompanying drawings. The following detailed description is provided to facilitate a comprehensive understanding of the methods, apparatuses, and/or systems described herein. However, the present disclosure is not limited to the embodiments shown and described below.

In describing the embodiments of the present disclosure, detailed descriptions of well-known technologies related to the disclosure may be omitted when it is determined that such detailed descriptions would unnecessarily obscure the subject matter of the embodiments. Further, the terms used herein are defined in consideration of the functions of the present disclosure and may vary depending on the intention of a user or an operator, or customary practice. Therefore, the definitions should be interpreted based on the entirety of this specification. The terms used in the detailed description are merely for describing embodiments and should not be construed as limiting. Unless clearly stated otherwise, singular expressions are intended to include plural meanings. In this description, the terms “include” and “have” indicate the presence of certain characteristics, numbers, steps, operations, elements, or combinations thereof, and should not be interpreted to exclude the presence or possibility of one or more other characteristics, numbers, steps, operations, elements, or combinations thereof in addition to those described. Moreover, the terms “unit,” “module,” and “block” as used herein refer to units that perform at least one function or operation, and may be implemented in hardware, software, or a combination of hardware and software.

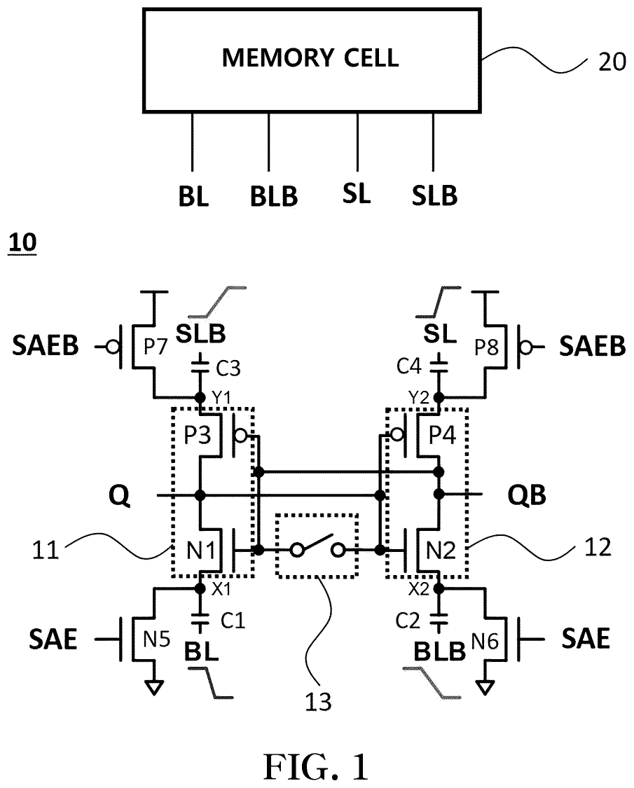

FIG. 1 is a schematic diagram illustrating a voltage sense amplifier according to an embodiment of this disclosure.

A voltage sense amplifier 10 according to an embodiment of the present disclosure may include a first inverter 11, a second inverter 12, first to fourth capacitors C1, C2, C3 and C4, and fifth to eighth transistors N5, N6, P7 and P8.

The first inverter 11 may include a first transistor N1 and a third transistor P3, and the second inverter 12 may include a second transistor N2 and a fourth transistor P4.

In the first inverter 11, the complementary output QB is connected to an input terminal, and the output Q is connected to an output terminal.

Conversely, in the second inverter 12, the output Q is connected to the input terminal, and the complementary output QB is connected to the output terminal.

The first inverter 11 and the second inverter 12 may be CMOS inverters.

Since the CMOS inverter outputs an inverted version of an input signal by using a pair of an nMOSFET (Metal-Oxide Semiconductor Field Effect Transistor) and a pMOSFET, the first transistor N1 and the second transistor N2 are nMOSFETs, and the third transistor P3 and the fourth transistor P4 are pMOSFETs.

The one end and the other end of each of the first inverter 11 and the second inverter 12 are connected to a bit line BL or a complementary bit line BLB, or to a source line SL or a complementary source line SLB, of the memory cell 20.

The memory cell 20 may be an MRAM memory cell having two transistors and two magnetic tunnel junctions (2T2MTJ) structure, but is not limited thereto.

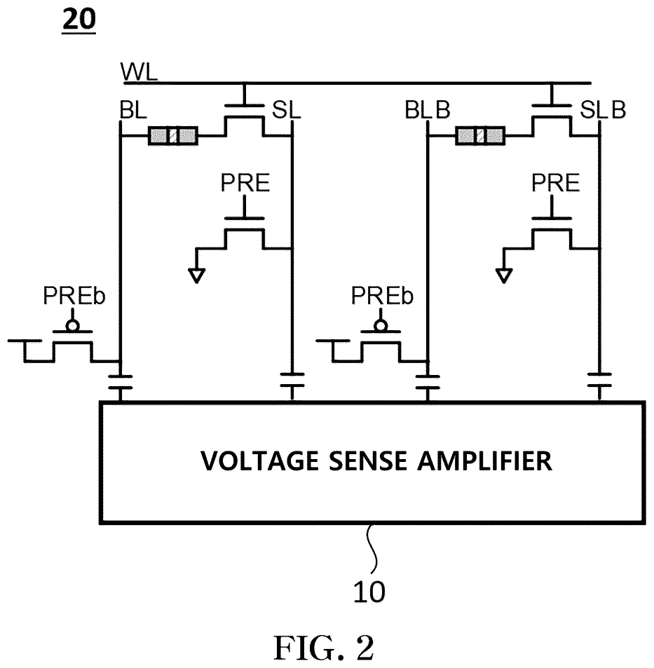

FIG. 2 illustrates an example of a memory cell to which a voltage sense amplifier according to an embodiment of the present disclosure is connected.

The memory cell 20 represents a 2T2MTJ-structured memory cell having two MTJ devices and two transistors.

In the related art, the source line and the complementary source line are driven to a ground voltage VSS during a read operation. In contrast, in the present disclosure, prior to the read operation, a precharge signal PRE/PREb causes the bit line and the complementary bit line to be charged to a supply voltage VDD, and the source line and the complementary source line to be discharged to VSS, and the difference is that charge-sharing is performed in this manner.

Accordingly, not only the voltage difference between the bit line and the complementary bit line but also the voltage difference between the source line and the complementary source line is utilized for sensing, thereby increasing the sensing margin.

Returning to FIG. 1, one end, that is, node X1, of the first inverter 11 is connected to the bit line of the memory cell 20, and the other end, that is, node Y1, is connected to the complementary source line of the memory cell.

One end, that is, node X2, of the second inverter 12 is connected to the complementary bit line of the memory cell 20, and the other end, that is, node Y2, is connected to the source line of the memory cell.

Here, a first capacitor C1 may be connected between the node X1 and the bit line, a second capacitor C2 may be connected between the node X2 and the complementary bit line, a third capacitor C3 may be connected between the node Y1 and the complementary source line, and a fourth capacitor C4 may be connected between the node Y2 and the source line.

The first to fourth capacitors C1, C2, C3 and C4 serve as coupling capacitors, and facilitate securing a sensing margin by continuously sensing voltage variations of the bit line and the complementary bit line, and of the source line and the complementary source line.

The nodes X1, X2, Y1 and Y2 are connected to a supply voltage and a ground voltage, respectively, for driving the inverters, and are connected through fifth to eighth transistors N5, N6, P7 and P8 that are controlled by a sense-amplifier enable signal SAE and a complementary sense-amplifier enable signal SAEB.

Specifically, the fifth transistor connects the node X1 to the ground voltage, the sixth transistor connects the node X2 to the ground voltage, the seventh transistor connects the node Y1 to the supply voltage, and the eighth transistor connects the node Y2 to the supply voltage.

Since the threshold voltages Vₜₕ of the first transistor N1 and the second transistor N2, which receive the bit-line and complementary bit-line voltages as sources, are stored in the nodes X1 and X2, respectively, during offset sampling, the mismatch between the first transistor N1 and the second transistor N2 can be eliminated, thereby achieving high sensing accuracy.

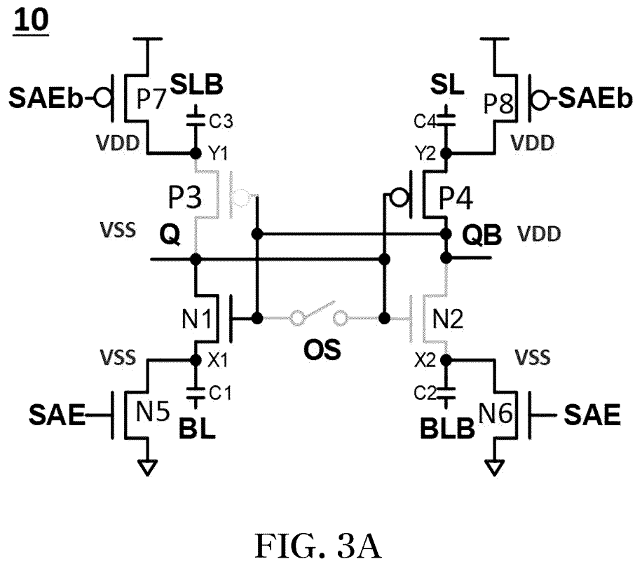

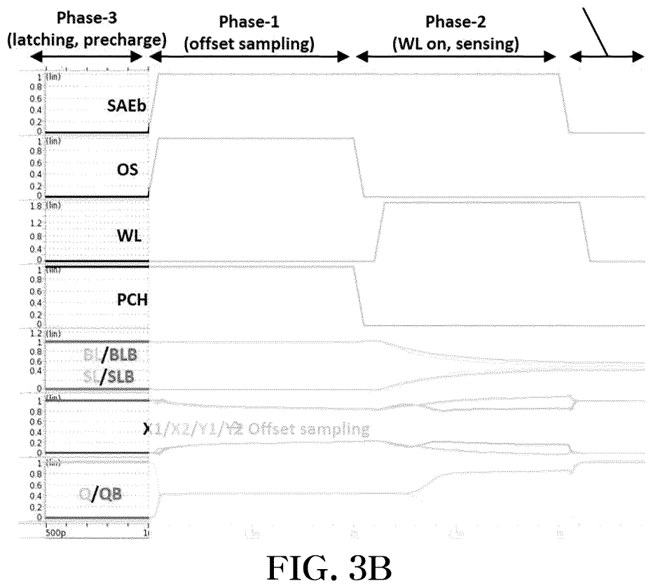

FIGS. 3A and 3B to FIGS. 6A and 6B illustrate schematic operations of respective stages of the voltage sense amplifier according to an embodiment of the present disclosure.

FIGS. 3A and 3B illustrate a precharge stage.

In the precharge stage, the fifth to eighth transistors N5, N6, P7 and P8 are turned on by the SAE/SAEB signals, such that the nodes X1 and X2 are precharged to the ground voltage, and the nodes Y1 and Y2 are precharged to the supply voltage.

A switch OS between the first transistor N1 and the second transistor N2 is in an open state.

The bit line and the complementary bit line are precharged to the supply voltage, and the source line and the complementary source line are precharged to the ground voltage.

The output Q and the complementary output QB of the voltage sense amplifier 10 remain latched to either the supply voltage or the ground voltage depending on a previous read state.

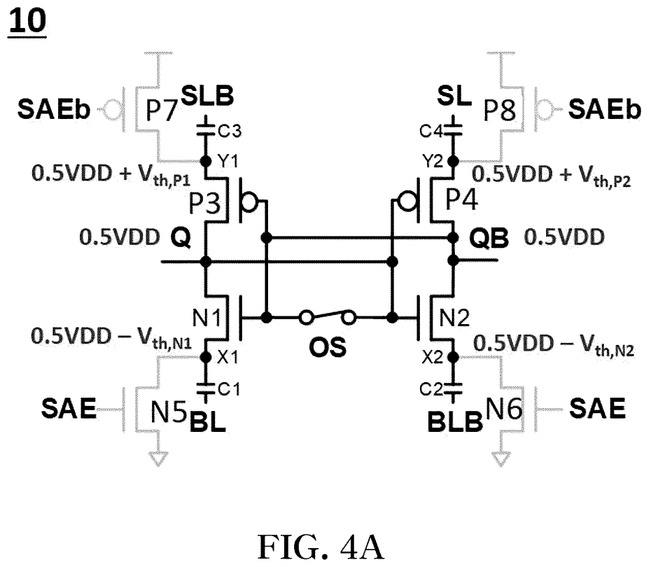

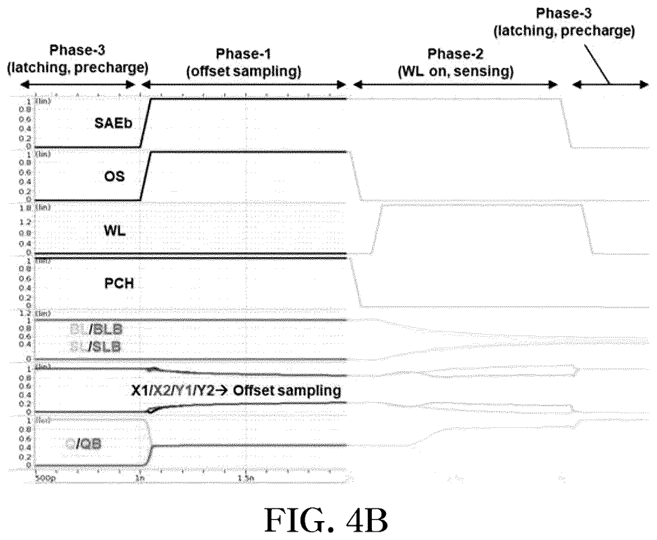

FIGS. 4A and 4B illustrate an offset sampling stage.

When the SAE/SAEB signals are switched to the ground/supply voltages, respectively, the fifth to eighth transistors N5, N6, P7 and P8 are turned off, and the nodes X1 and X2 become floating at the ground voltage, while the nodes Y1 and Y2 become floating at the supply voltage.

When the switch OS between the first transistor N1 and the second transistor N2 is turned on, charge-sharing occurs between the precharged output Q and the complementary output QB, and accordingly, both the output and the complementary output become 0.5 VDD.

When the output Q and the complementary output QB become equal, the first to fourth transistors N1, N2, P3 and P4 enter a diode-connected transistor state. Accordingly, offset sampling is performed such that the voltages of the nodes X1, X2, Y1 and Y2 change as expressed by the following equations:

$$X 1 / X 2 = ( {V}_{Q} - {V}_{th , N 1} ) / ( {V}_{Q} - {V}_{th , N 2} )$$

$$Y 1 / Y 2 = ( {V}_{Q} + {V}_{th , P 3} ) / ( {V}_{Q} + {V}_{t h , P 4} )$$

V_{Q}: Q node voltage
V_{th, m}: threshold voltage of transistor m

At this time, the bit line and the complementary bit line remain precharged to the supply voltage, and the source line and the complementary source line remain precharged to the ground voltage.

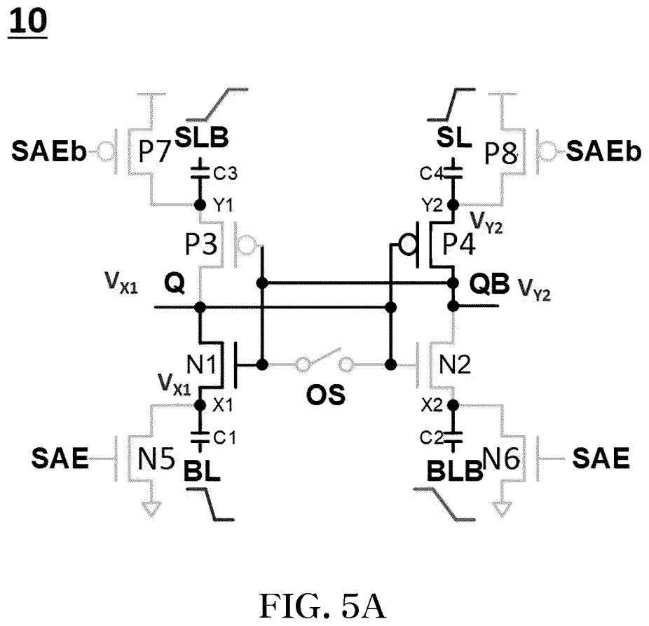

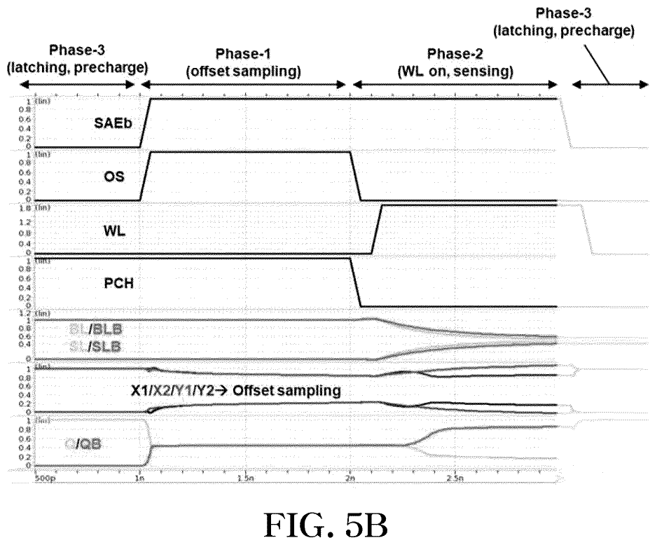

FIGS. 5A and 5B illustrate a sensing stage.

In the sensing stage, when the word line WL signal is turned on, charge-sharing occurs between the bit line and the source line, and between the complementary bit line and the complementary source line.

However, due to the resistance difference of the MTJ devices included in the memory cell 20, a difference occurs between a discharge speed of the bit line and the complementary bit line and a charging speed of the source line and the complementary source line.

For example, if the resistance between the bit line and the source line of the memory cell 20 is in a low-resistance state (R_{LRS}), and the resistance between the complementary bit line and the complementary source line is in a high-resistance state (R_{HRS}), the discharge and charging speed between the bit line and the source line becomes faster than the discharge and charging speed between the complementary bit line and the complementary source line.

As a result, the voltage changes of the node X1 and node Y2 become greater than the voltage changes of the node X2 and node Y1, and the relationships can be expressed by the following equations:

$${V}_{G S , N 1} = {V}_{th , N 1} + Δ BL , {V}_{G S , N 2} = {V}_{th , N 2} + Δ BLB \to Δ BL - Δ BLB$$

$${V}_{G S , P 3} = - {V}_{t h , P 4} - Δ SLB , {V}_{G S , P 4} = - {V}_{th , N 2} - Δ SL \to Δ SL - Δ SLB$$

V_{GS, m}: gate-to-source voltage of transistor m

At this time, since ΔBL is greater than ΔBLB, the first transistor N1 becomes stronger, and since ΔSL is greater than ΔSLB, the fourth transistor P4 becomes stronger.

When the first transistor N1 and the fourth transistor P4 become stronger than the second transistor N2 and the third transistor P3, the output Q is discharged, and the complementary output QB is charged, resulting in a relationship of Q=V_{X1}<QB=V_{Y2}, such that Q and QB diverge as illustrated in FIG. 5B.

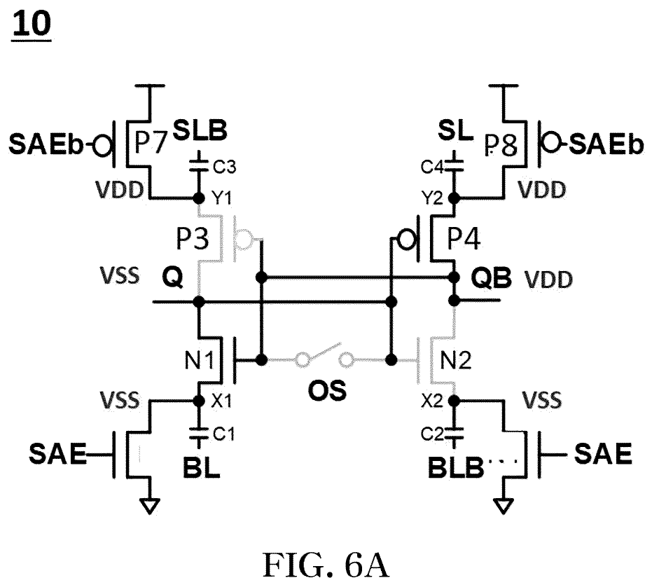

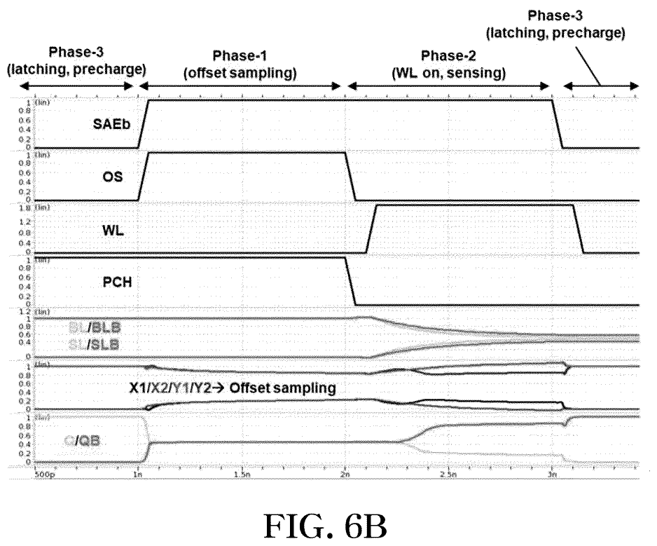

FIGS. 6A and 6B illustrate a final latching stage.

In the latching stage, since the SAE signal is switched back to the supply voltage, the fifth to eighth transistors N5, N6, P7 and P8 are turned on, such that the nodes X1 and X2 are driven to the ground voltage, and the nodes Y1 and Y2 are driven to the supply voltage.

The output voltage Q becomes the voltage of node X1 (Q=V_{X1}), and the complementary output voltage QB becomes the voltage of node Y2 (QB=V_{Y2}). Accordingly, the output of the voltage sense amplifier 10 is latched to the ground voltage VSS, and the complementary output is latched to the supply voltage VDD.

After latching, when the operation returns to the precharge stage of FIGS. 3A and 3B and the precharge signal PRE is turned on, the bit line and the complementary bit line, and the source line and the complementary source line, are precharged again, and the voltage sense amplification operation may be repeated.

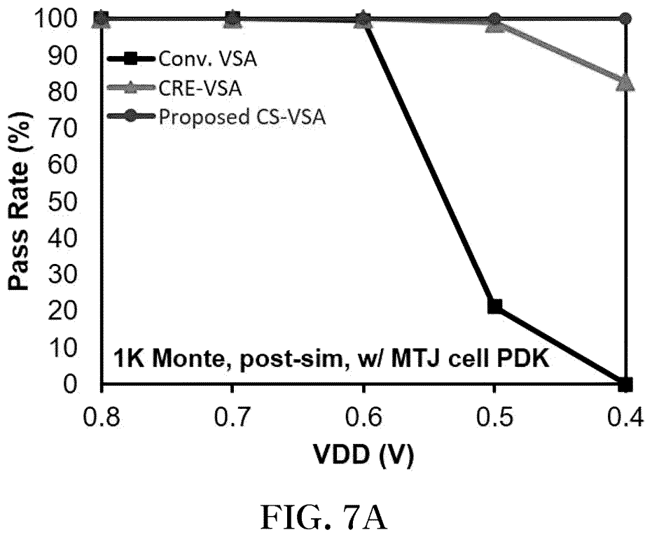

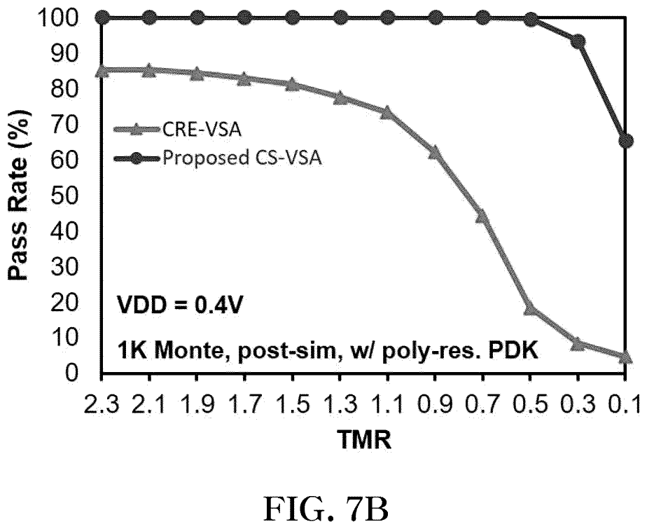

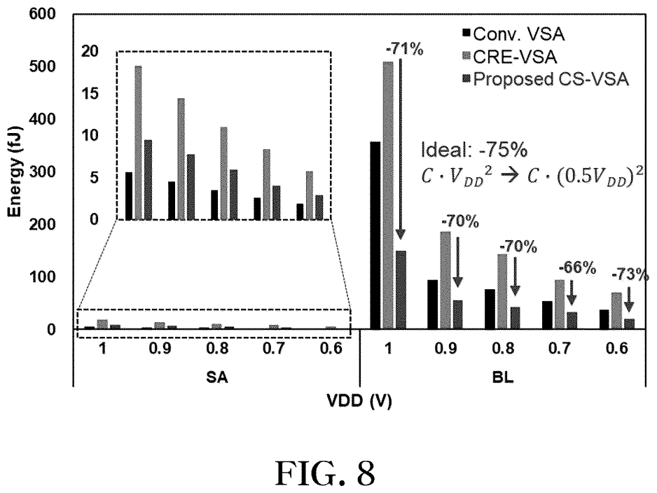

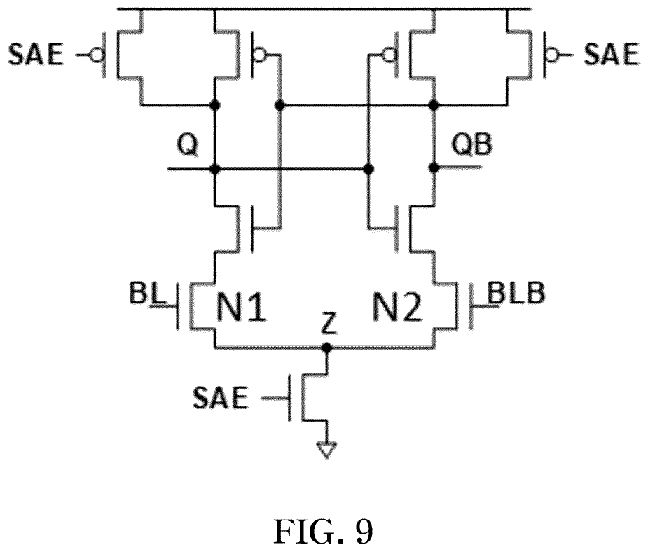

FIGS. 7A, 7B and 8 illustrate performance simulation results of the voltage sense amplifier according to an embodiment of the present disclosure.

In FIGS. 7A and 7B, sensing performance simulation results are illustrated.

Referring to FIG. 7A, it can be seen that, according to the present disclosure (Proposed CS-VSA), the performance does not degrade even when the supply voltage is reduced below 0.5 V, in contrast to the related art (Conv. VSA, CRE-VSA). This indicates that, by employing the charge-sharing scheme, sensing performance can be improved even near the threshold voltage region of the transistors, thereby eliminating the sensing dead zone.

Referring to FIG. 7B, it can be seen that the proposed technique maintains superior performance compared to the related art even with variations in the tunnel magnetoresistance (TMR).

FIG. 8 illustrates a comparison of precharge power.

According to the present disclosure, since the bit line and the complementary bit line and the source line and the complementary source line are precharged together, the voltage to be charged and discharged can be reduced to one half, thereby demonstrating that the power consumed for precharging can be reduced by up to 75%.

According to the voltage sense amplifier VSA for the MRAM memory cell of the present disclosure, by precharging the bit line and the complementary bit line and the source line and the complementary source line in advance using a charge-sharing scheme and utilizing them for voltage sensing amplification, sensing performance in a low-voltage region can be improved, and a sensing dead zone can be eliminated. In addition, the overall power consumption of the memory can be reduced by decreasing the power required for precharging after discharging.

The scope of the present disclosure is not limited to the descriptions and expressions of the embodiments explicitly set forth above. It is also to be understood that various modifications, changes, and substitutions that are obvious to those skilled in the art may be made without departing from the spirit or scope of the present disclosure as defined by the appended claims.

What is claimed is:

1. A voltage sense amplifier for sensing and amplifying a bit-line voltage of a memory cell, comprising:
a first inverter having an input terminal coupled to a complementary output QB of the voltage sense amplifier and an output terminal coupled to an output Q of the voltage sense amplifier;
a second inverter having an input terminal coupled to an output Q of the voltage sense amplifier and an output terminal coupled to a complementary output QB of the voltage sense amplifier;
a first transistor configured to connect a ground voltage VSS and a node X1, which is one end of the first inverter, in response to a sense-amplifier enable signal SAE;
a second transistor configured to connect the ground voltage VSS and a node X2, which is one end of the second inverter, in response to the sense-amplifier enable signal;
a third transistor configured to connect a supply voltage VDD and a node Y1, which is the other end of the first inverter, in response to a complementary sense-amplifier enable signal SAEB; and
a fourth transistor configured to connect the supply voltage VDD and a node Y2, which is the other end of the second inverter, in response to the complementary sense-amplifier enable signal,
wherein a bit line and a complementary bit line are precharged to the supply voltage VDD prior to a read operation of the memory cell, and
wherein a source line and a complementary source line are precharged to the ground voltage VSS prior to the read operation of the memory cell.

2. The voltage sense amplifier of claim 1, further comprising:
a first capacitor connected between the node X1 and the bit line of the memory cell;
a third capacitor connected between the node Y1 and the complementary source line of the memory cell;
a second capacitor connected between the node X2 and the complementary bit line of the memory cell; and
a fourth capacitor connected between the node Y2 and the source line of the memory cell.

3. The voltage sense amplifier of claim 1, wherein the memory cell is a 2T2MTJ-structured memory cell including two transistors and two magnetic tunnel junctions (MTJs).

4. The voltage sense amplifier of claim 1, wherein the first and second transistors are n-type metal-oxide semiconductor field effect transistors (nMOSFETs), and
the third and fourth transistors are p-type metal-oxide semiconductor field effect transistors (pMOSFETs).

5. The voltage sense amplifier of claim 1, further comprising:
a switch connected between an input of the first inverter and an input of the second inverter and configured to equalize voltages between the inputs.

6. The voltage sense amplifier of claim 5, wherein, after the precharge, a sense-amplifier enable signal is switched to the ground voltage and a complementary sense-amplifier enable signal is switched to the supply voltage, such that the first to fourth transistors are turned off, the nodes X1 and X2 become floating at the ground voltage, the nodes Y1 and Y2 become floating at the supply voltage, and the switch is turned on and connects the input of the first inverter and the input of the second inverter, whereby offset sampling is performed in which both the output and the complementary output of the voltage sense amplifier are equalized to one half of the supply voltage.

7. The voltage sense amplifier of claim 6, wherein, after the offset sampling, a word line of the memory cell is turned on such that the bit line and the complementary bit line are discharged and the source line and the complementary source line are charged, and a voltage difference between the output and the complementary output of the voltage sense amplifier is amplified due to a difference in discharge and charging speeds caused by a resistance difference of the memory cell.

8. The voltage sense amplifier of claim 7, wherein, after the amplification of the voltage difference, the sense-amplifier enable signal is switched to the supply voltage and the complementary sense-amplifier enable signal is switched to the ground voltage such that the first to fourth transistors are turned on, the nodes X1 and X2 are driven to the ground voltage, and the nodes Y1 and Y2 are driven to the supply voltage, whereby the output and the complementary output of the voltage sense amplifier are latched to the supply voltage or the ground voltage.
